(19) United States
(12) Patent Application Publication
(10) Pub. No.: US 2008/0150084 A1
(43) Pub. Date: Jun. 26, 2008

(54) Phosphorus-Stabilized Transition Metal Oxide Diffusion Barrier

(75) Inventors: Peter Hacke, Albuquerque, NM (US); Victoria Gonzales, Albuquerque, NM (US); Jason Dominguez, Albuquerque, NM (US)

Correspondence Address: PEACOCK MYERS, P.C., 201 THIRD STREET, N.W., SUITE 1340, ALBUQUERQUE, NM, 87102, US

(73) Assignee: ADVENT SOLAR, INC., Albuquerque, NM (US)

(21) Appl. No.: 11/949,679

(22) Filed: Dec. 3, 2007

Related U.S. Application Data
(60) Provisional application No. 60/868,267, filed on Dec. 1, 2006.

(51) Int. Cl. H01L 29/00; H01L 21/22

(52) U.S. Cl. 257/607; 438/542; 257/E21.135; 257/E29.001

(57) ABSTRACT

Method for controlling glass formation on a semiconductor substrate. By using a doped diffusion barrier material, such as a transition metal oxide paste, the subsequent diffusion of glass forming elements into the substrate may be stabilized and controlled.

### CROSS-REFERENCE TO RELATED APPLICATIONS

This application claims priority to and the benefit of filing of U.S. Provisional Patent Application Ser. No. 60/868,267, entitled “Phosphorus-Stabilized Transition Metal Oxide Diffusion Barrier”, filed on Dec. 1, 2006, which is incorporated herein by reference.

### BACKGROUND OF THE INVENTION

1. Field of the Invention (Technical Field)

The present invention is a method and composition for controlling the deposition of oxides on the surface of a semiconductor when using a diffusion barrier.

2. Description of Related Art

Note that the following discussion refers to a number of publications by author(s) and year of publication, and that due to recent publication dates certain publications are not to be considered as prior art vis-à-vis the present invention. Discussion of such publications herein is given for more complete background and is not to be construed as an admission that such publications are prior art for patentability determination purposes.

Transition metal oxides are often used as a diffusion barrier (DB) to impede the in-diffusion of elements, including but not limited to Group III and V elements, into semiconductors such as silicon. One application is the manufacturing of solar or photovoltaic cells. POCl₃ is a compound that when reacted with O₂ may be used to form a phosphorus oxide on the surface of Si. At suitably high temperatures, the group V element (e.g. phosphorus) will diffuse into Si. The use of a transition metal oxide as a diffusion barrier on the surface of the Si can prevent this process from occurring in the Si underneath it.

However, the existence of transition metal oxides on the surface of the Si tends to accelerate the deposition of the phosphorus oxide on the Si surface. This is especially apparent at and around the areas where the transition metal oxide is placed. This interaction between the transition metal oxide and the phosphorus that is introduced through POCl₃ may be beneficial or deleterious depending on the desired application. For example, excess phosphorus glass build up may correspond to increased defect density in the Si, and is thus typically undesirable.

### BRIEF SUMMARY OF THE INVENTION

The present invention comprises a method for controlling glass formation on a semiconductor substrate, the method comprising the steps of doping a diffusion barrier material with a dopant, depositing the diffusion barrier material on one or more areas of a surface of the semiconductor substrate, thereby forming a diffusion barrier, subsequently depositing a diffusion comprising an element on the surface, and forming a glass on the surface with the element. The dopant preferably comprises a group V element, preferably phosphorous. The diffusion barrier material preferably comprises a paste, and preferably comprises a transition metal oxide, preferably TiO₂. The diffusion preferably comprises POCl₃. The glass preferably comprises a phosphorous glass. The forming step preferably comprises reacting the diffusion with oxygen. The element is preferably the same as the dopant. The method preferably further comprises the step of controlling the diffusion of the element to the semiconductor surface. The method preferably further comprises the step of reducing the thickness of the glass.

The present invention is also a diffusion barrier on a semiconductor surface, the diffusion barrier formed from a transition metal oxide paste comprising a dopant. The dopant preferably comprises a group V element, preferably phosphorous. The transition metal oxide preferably comprises TiO₂. The dopant preferably controls subsequent glass formation on the surface. The dopant preferably reduces the subsequent glass formation on the surface. The dopant preferably increases the uniformity of subsequent glass formation on the surface.

An object of the present invention is to provide a method for improving the control of oxide deposition or formation on semiconductor wafers.

An advantage of the present invention is that the amount of phosphorous oxide deposited or formed on a silicon wafer may be modulated as desired.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawing, which is incorporated into and form a part of the specification, illustrates an embodiment of the present invention and, together with the description, serves to explain the principles of the invention. The drawing is only for the purpose of illustrating an example of the invention and is not to be construed as limiting the invention. In the drawings:

FIG. 1 shows sheet resistivities of a wafer an undoped TiO₂ diffusion barrier and a phosphorous-doped TiO₂ diffusion barrier.

### DETAILED DESCRIPTION OF THE INVENTION

In an embodiment of the present invention, addition of a compound or element, preferably a group V element such as phosphorus, into a transition metal oxide compound that is placed on the Si as a diffusion barrier, preferably modulates the extent to which the deposition of phosphorus oxide on the surface of the Si is accelerated. Transition metal oxides such as TiO₂ and tantalum oxide are known to have catalytic properties. The addition of the group V element to the diffusion barrier material, e.g. a paste, preferably modulates the catalytic effect of the transition metal oxide on the reaction between, for example, POCl₃ and O₂ and its decomposition into P₂O₅ glass (or another oxide) on the wafer surface.

The group V element may be included into the system any number of ways, such as disposing a group V compound near, on top of, or mixed in the transition metal DB compound. For example, phosphorus-containing paste may be screen printed on areas adjacent to or on top of (or both) the locations of a TiO₂ diffusion barrier on the product wafer. Alternatively, phosphorus or another suitable element or compound may be mixed in with the TiO₂ diffusion barrier paste (or other applied material). In the case of a group V or other element being mixed with the transition metal oxide, any desired ratio of phosphorus may be employed, depending on the application. The desired element (preferably phosphorus) is preferably present in the transition metal oxide (preferably TiO₂) in a range from approximately 0.1% to approximately 10% by weight; the most preferable concentration is approximately 0.7 wt %.

This addition of phosphorus into the transition metal oxide preferably modulates the amount of phosphorus glass that is deposited during the reaction of subsequently-deposited POCl₃ and O₂ on the surface of the Si at and around the diffusion barrier. If increased phosphorus is included in the transition metal oxide DB, the amount of phosphorus glass deposited in the vicinity will preferably be reduced. Thus rates of phosphorus glass build up are preferably tunable over the wafer surface. In addition, performance of the DB will preferably be improved because less phosphorus glass will be deposited in that region. Also, because phosphorus preferably binds the transition metal oxide, better surface passivation and diffusion barrier properties are preferably achieved.

### EXAMPLE 1

For one type of solar cell, the width of the DB lines which are screen printed or otherwise deposited onto the cell is preferably approximately 0.3 μm. The space between these lines is preferably about 0.7 μm. Elemental phosphorus was introduced in a number of ways, including screen printing phosphorus approximately within the 0.7 μm spaces and screen printing phosphorus over approximately the entire back surface (i.e. on both the bare Si and on the previously printed DB lines) before deposition of P₂O₅ by the POCl₃+O₂ reaction. It was observed that the catalytic effect of the TiO₂ that accelerates the deposition of phosphorus glass on the Si surface was stabilized and is therefore reducible.

### EXAMPLE 2

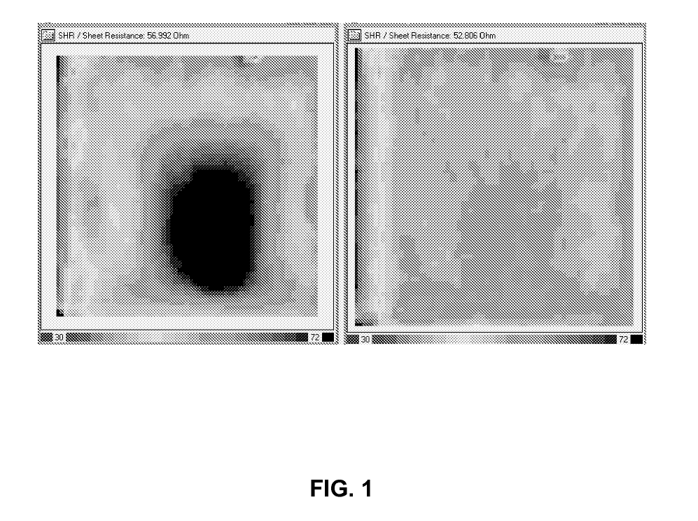

The stabilization also preferably provides increased uniformity of the phosphorous diffusion, i.e. the P₂O₅ glass thickness, across the wafer. FIG. 1 shows sheet resistance maps of two wafers. The wafer on the left had TiO₂ diffusion barrier paste applied to substantially the entire wafer surface before POCl₃ diffusion and shows a large region of higher resistivity due to a non-uniform phosphorous glass diffusion. In contrast, the wafer on the right utilized phosphorous-doped TiO₂ diffusion barrier paste; the resistivity is far more uniform across the wafer.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all references, applications, patents, and publications cited above and/or in the attachments, and of the corresponding application(s), are hereby incorporated by reference.

What is claimed is:

1. A method for controlling glass formation on a semiconductor substrate, the method comprising the steps of:
doping a diffusion barrier material with a dopant;
depositing the diffusion barrier material on one or more areas of a surface of the semiconductor substrate, thereby forming a diffusion barrier;
subsequently depositing a diffusion comprising an element on the surface; and
forming a glass on the surface with the element.

2. The method of claim 1 wherein the dopant comprises a group V element.

3. The method of claim 2 wherein the dopant comprises phosphorous.

4. The method of claim 1 wherein the diffusion barrier material comprises a paste.

5. The method of claim 1 wherein the diffusion barrier material comprises a transition metal oxide.

6. The method of claim 5 wherein the diffusion barrier material comprises TiO₂.

7. The method of claim 1 wherein the diffusion comprises POCl₃.

8. The method of claim 1 wherein the glass comprises a phosphorous glass.

9. The method of claim 1 wherein the forming step comprises reacting the diffusion with oxygen.

10. The method of claim 1 wherein the element is the same as the dopant.

11. The method of claim 1 further comprising the step of controlling the diffusion of the element to the semiconductor surface.

12. The method of claim 1 further comprising the step of reducing the thickness of the glass.

13. A diffusion barrier on a semiconductor surface, the diffusion barrier formed from a transition metal oxide paste comprising a dopant.

14. The diffusion barrier of claim 13 wherein said dopant comprises a group V element.

15. The diffusion barrier of claim 14 wherein said dopant comprises phosphorous.

16. The diffusion barrier of claim 11 wherein said transition metal oxide comprises TiO₂.

17. The diffusion barrier of claim 11 wherein said dopant controls subsequent glass formation on the surface.

18. The diffusion barrier of claim 17 wherein said dopant reduces the subsequent glass formation on the surface.

19. The diffusion barrier of claim 11 wherein said dopant increases the uniformity of subsequent glass formation on the surface.
